(19) United States
(12) Patent Application Publication
(10) Pub. No.: US 2013/0161749 A1
(43) Pub. Date: Jun. 27, 2013

(54) SEMICONDUCTOR INTEGRATED CIRCUIT

(71) Applicant: Jang-Hoo KIM, Gyeonggi-do (KR)

(72) Inventor: Jang-Hoo KIM, Gyeonggi-do (KR)

(21) Appl. No.: 13/467,150

(22) Filed: May 9, 2012

(30) Foreign Application Priority Data
Dec. 21, 2011 (KR) 10-2011-0139639

(51) Int. Cl. H01L 27/06; H01L 23/50

(52) U.S. Cl. 257/355; 257/503; 257/E23.079; 257/E27.015; 257/E27.016

(57) ABSTRACT

A semiconductor integrated circuit includes: a first conductive line coupled with a first pad for receiving a first voltage; a second conductive line coupled with a second pad for receiving a second voltage; a third conductive line arranged to be placed in a floating state; a first electrostatic discharge unit coupled between a third pad for inputting/outputting a signal and the third conductive line through a first common conductive line, wherein the first electrostatic discharge unit is configured to provide a bi-directional electrostatic discharge path between the third pad and the third conductive line according to an electrostatic discharge mode; a second electrostatic discharge unit coupled between the first conductive line and the third conductive line through a second common conductive line; and a third electrostatic discharge unit coupled between the second conductive line and the third conductive line through a third common conductive line.

### CROSS-REFERENCE TO RELATED APPLICATIONS

The present application claims priority of Korean Patent Application No. 10-2011-0139639, filed on Dec. 21, 2011, which is incorporated herein by reference in its entirety.

### BACKGROUND

1. Field

Exemplary embodiments of the present invention relate to a semiconductor integrated circuit, and more particularly, to an electrostatic discharge protection circuit.

2. Description of the Related Art

Generally, electrostatic discharge (ESD) refers to a phenomenon that current instantaneously flows due to a high voltage difference between two objects that are insulated from each other, when the two objects contact each other. Therefore, when such static electricity current occurs, internal circuits may be damaged. For example, an insulation layer of a transistor may be destroyed or a junction of a resistor may be broken. Therefore, an electrostatic discharge path may be used to discharge electrostatic currents to prevent damage to internal components of a semiconductor integrated circuit.

Meanwhile, the electrostatic discharge phenomenon may be divided into two cases according to the direction that charges are discharged. In the first case, the voltage level of an external object is higher than the voltage level of a semiconductor integrated circuit. In the second case, the voltage level of an external object is lower than the voltage level of a semiconductor integrated circuit. In the first case, the electrostatic discharge current flows from the external object to the semiconductor integrated circuit. In the second case, the electrostatic discharge current flows from the semiconductor integrated circuit to the external object. Common situations where the electrostatic discharge currents may occur are as follows. In a first situation, when a human being or equipment contacts a semiconductor integrated circuit, a large amount of charge may instantaneously flow to the semiconductor integrated circuit through an input pin or an output pin of the semiconductor integrated circuit. In a second situation, a large amount of charge accumulated in the semiconductor integrated circuit may be discharged to the outside when the semiconductor integrated circuit including the accumulated charges is mounted on a printed circuit board or when a pin contacts an external object while the semiconductor integrated circuit is being transported.

This disclosure may relate to different models of electrostatic discharge including a Human Body Model (HBM), a Machine Model (MM), and a Charged Device Model (CDM). The Human Body Model (HBM) is an electrostatic discharge model where electrostatic discharge is caused by a human being, where the static electricity from a human body is instantaneously discharged through a semiconductor integrated circuit. The Machine Model (MM) is an electrostatic discharge model where an electrostatic discharge is caused by equipment. For example, the static electricity generated by a charged worktable or instrument is instantaneously discharged through a semiconductor integrated circuit. The Charged Device Model (CDM) is an electrostatic discharge model where an electrostatic discharge occurs as a package of a semiconductor integrated circuit is charged with positive or negative charge in the course of a product assembling process and the accumulated charge of a semiconductor integrated circuit is discharged instantaneously.

FIG. 1 is a block view of a semiconductor integrated circuit 100 according to a prior art.

Referring to FIG. 1, the semiconductor integrated circuit 100 includes an electrostatic discharge protection circuit 107, 108 and 109 for protecting internal circuits 104, 105 and 106 from static electricity generated between a high-voltage pad 101, a low-voltage pad 102, and an input/output pad 103.

The electrostatic discharge protection circuit 107, 108 and 109 includes a first electrostatic discharge unit 107, a second electrostatic discharge unit 108, and a clamping unit 109. The electrostatic discharge protection circuit 107, 108 and 109 is normally disabled in order not to affect a normal operation of the semiconductor integrated circuit 100. The electrostatic discharge protection circuit 107, 108 and 109 is enabled to perform an electrostatic discharge operation, when static electricity is introduced through the high-voltage pad 101, the low-voltage pad 102, and/or the input/output pad 103. For example, the electrostatic discharge protection circuit 107, 108 and 109 that performs the aforementioned operations may be realized as shown in FIG. 2.

Referring to FIG. 2, each of the first electrostatic discharge unit 107 and the second electrostatic discharge unit 108 includes a diode D1 and a diode D2, respectively, and the clamping unit 109 includes a capacitor C1, a resistor R1, and an NMOS transistor N1.

The semiconductor integrated circuit 100 may lose some efficiency in performing a high-speed operation due to the presence of a junction capacitance of the first electrostatic discharge unit 107 and the second electrostatic discharge unit 108 that are coupled in parallel to the input/output pad 103, and occupies a large area due to the presence of the clamping unit 109 provided for each input/output pad 103.

FIG. 3 is a block view of another semiconductor integrated circuit according to prior art.

Referring to FIG. 3, the semiconductor integrated circuit 200 includes a high voltage line PL11, a low voltage line PL12, a floating-state electrostatic discharge bus line BL11, an input/output pad 202 coupled with an internal circuit 201, a first electrostatic protection unit 203 and a second electrostatic protection unit 204 that are coupled between the input/output pad 202 and the floating-state electrostatic discharge bus line BL11, a third electrostatic protection unit 205 coupled between the high voltage line PL11 and the floating-state electrostatic discharge bus line BL11, and a fourth electrostatic protection unit 206 coupled between the low voltage line PL12 and the floating-state electrostatic discharge bus line BL11.

The first electrostatic protection unit 203 includes a diode D11 that includes an anode terminal coupled with the floating-state electrostatic discharge bus line BL11 and a cathode terminal coupled with the input/output pad 202. The second electrostatic protection unit 204 includes a diode D12 having an anode terminal coupled with the input/output pad 202 and a cathode terminal coupled with the floating-state electrostatic discharge bus line BL11. The third electrostatic protection unit 205 includes an NMOS transistor N11 having a gate and a source coupled with the floating-state electrostatic discharge bus line BL11 and a drain coupled with the high voltage line PL11. The fourth electrostatic protection unit 206 includes an NMOS transistor N12 having a gate and a source coupled with the low voltage line PL12 and a drain coupled with the floating-state electrostatic discharge bus line BL11.

The semiconductor integrated circuit 200 having the above-described structure has an electrostatic discharge path formed of the high voltage line PL11 or the low voltage line PL12 by using the floating-state electrostatic discharge bus line BL11. In this case, the area of the semiconductor integrated circuit 200 may be reduced while not decreasing electrostatic protection performance and the junction capacitance at the input/output pad 202 may be reduced by use of the first to fourth electrostatic protection units 203, 204, 205 and 206 that are serially coupled for each electrostatic discharge path.

FIG. 4 is a block view of another semiconductor integrated circuit according to prior art. The semiconductor integrated circuit shown in FIG. 4 has an even more reduced area of the semiconductor integrated circuit and reduced junction capacitance at an input/output pad than the semiconductor integrated circuit shown in FIG. 3.

Referring to FIG. 4, the semiconductor integrated circuit 300 includes a high voltage line PL21, a low voltage line PL22, an electrostatic discharge bus line BL21, a plurality of PN diodes 302, an NP diode 303, an NMOS transistor 304, and an input/output pad 301 coupled with an internal circuit 305. The electrostatic discharge bus line BL21 includes a divergent line coupled with the low voltage line PL22. Each of the PN diodes 302 includes a cathode coupled with the electrostatic discharge bus line BL21 and an anode coupled with an input/output pad 301. The NP diode 303 includes a cathode coupled with the input/output pad 301 and an anode coupled with the electrostatic discharge bus line BL21 and the low voltage line PL22. The NMOS transistor 304 includes a drain coupled with the high voltage line PL21 and includes a gate and a source coupled with the electrostatic discharge bus line BL21.

The semiconductor integrated circuit 300 having the above-described structure has a decreased leakage current as the multiple PN diodes 302 are serially coupled between the electrostatic discharge bus line BL21 and the input/output pad 301, and has a decreased equivalent capacitance due to the serially coupled PN diodes 302. The decreased equivalent capacitance leads to a decrease in the junction capacitance for the PN diodes 302. Also, as the NP diode 303 coupled between a node coupled with the electrostatic discharge bus line BL21 and the low voltage line PL22 and the input/output pad 301 replaces a conventional clamping unit, the overall area of the semiconductor integrated circuit 300 is reduced.

The conventional semiconductor integrated circuits 200 and 300, however, have the following features. When the conventional semiconductor integrated circuits 200 and 300 are applied to a high voltage environment, the number of diodes 203, 204 and 302 in a chain is increased in proportion to reduce leakage current. Therefore, the area of the semiconductor integrated circuits 200 and 300 increases due to the increased numbers of diodes 203, 204 and 302 in a high voltage environment.

### SUMMARY

An embodiment of the present invention is directed to a semiconductor integrated circuit that may be applied to a high voltage environment and has a minimized/reduced area of an electrostatic discharge protection circuit that protects internal circuits from static electricity.

Another embodiment of the present invention is directed to a semiconductor integrated circuit that may easily estimate electrostatic discharge properties in designing an electrostatic discharge protection circuit that protects internal circuits from static electricity, while minimizing the junction capacitance at an input/output pad.

In accordance with an embodiment of the present invention, a semiconductor integrated circuit includes: a first conductive line coupled with a first pad for receiving a first voltage; a second conductive line coupled with a second pad for receiving a second voltage; a third conductive line arranged to be placed in a floating state; a first electrostatic discharge unit coupled between a third pad for inputting/outputting a signal and the third conductive line through a first common conductive line, wherein the first electrostatic discharge unit is configured to provide a bi-directional electrostatic discharge path between the third pad and the third conductive line according to an electrostatic discharge mode; a second electrostatic discharge unit coupled between the first conductive line and the third conductive line through a second common conductive line, wherein the second electrostatic discharge unit is configured to provide a bi-directional electrostatic discharge path between the first conductive line and the third conductive line according to the electrostatic discharge mode; and a third electrostatic discharge unit coupled between the second conductive line and the third conductive line through a third common conductive line, wherein the third electrostatic discharge unit is configured to provide a bi-directional electrostatic discharge path between the second conductive line and the third conductive line according to the electrostatic discharge mode.

In accordance with another embodiment of the present invention, a semiconductor integrated circuit includes: a first pad arranged to receive a first voltage; a first conductive line coupled with the first pad; a second pad arranged to receive a second voltage; a second conductive line coupled with the second pad; a third conductive line in a floating state; a third pad arranged to input/output a signal between an internal circuit and an external circuit; a first NMOS transistor including a gate, a source, and a substrate that are coupled with the third conductive line and including a drain coupled with the third pad; a second NMOS transistor including a gate, a source, and a substrate that are coupled with the third conducive line and including a drain coupled with the first conductive line; and a third electrostatic discharge unit including a gate, a source, and a substrate that are coupled with the third conductive line and including a drain coupled with the second conductive line.

In accordance with yet another embodiment of the present invention, a semiconductor integrated circuit includes: a first pad arranged to receive a first voltage; a first conductive line coupled with the first pad; a second pad arranged to receive a second voltage; a second conductive line coupled with the second pad; a third conductive line arranged to be placed in a floating state; a third pad arranged to input/output a signal between an internal circuit and an external circuit; a first NMOS transistor including a drain coupled with the third conductive line and including a gate, a source, and a substrate that are coupled with the third pad; a second NMOS transistor including a drain coupled with the third conductive line and including a gate, a source, and a substrate that are coupled with the first conductive line; and a third NMOS transistor including a drain coupled with the third conductive line and including a gate, a source, and a substrate that are coupled with the second conductive line.

In accordance with yet another embodiment of the present invention, a semiconductor integrated circuit includes: first to third electrostatic discharge units that are each configured to be turned on as a diode or a transistor switch depending upon a polarity of voltage applied across the electrostatic discharge unit; and first to third pads coupled to a common conductive line through the first to third electrostatic discharge units, respectively, wherein in an electrostatic discharge path formed between a third pad and one of the first and second pads, a trigger voltage to turn on the electrostatic discharge path is the same regardless of whether the electrostatic discharge path is formed to flow current in one direction or in an opposite direction and the trigger voltage is the same regardless of whether the electrostatic discharge path formed between the third pad and the first pad or between the third pad and the second pad.

### BRIEF DESCRIPTION OF THE DRAWINGS

FIG. 1 is a block view of a semiconductor integrated circuit according to a prior art.

FIG. 2 is a block view illustrating first and second electrostatic discharge units and a clamping unit shown in FIG. 1.

FIG. 3 is a block view of a semiconductor integrated circuit according to another prior art.

FIG. 4 is a block view of a semiconductor integrated circuit according to yet another prior art.

FIG. 5 is a block view of a semiconductor integrated circuit in accordance with a first embodiment of the present invention.

FIG. 6 is a graph showing turn-on characteristics during a parasitic bipolar operation of an NMOS transistor.

FIG. 7 is a block view of a semiconductor integrated circuit in accordance with a second embodiment of the present invention.

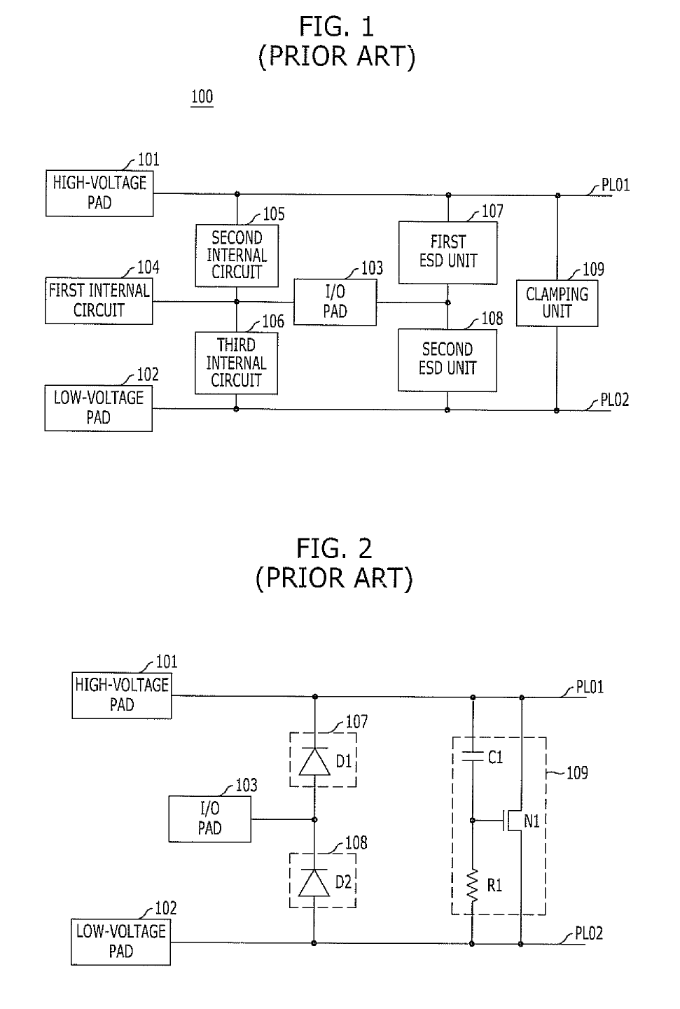

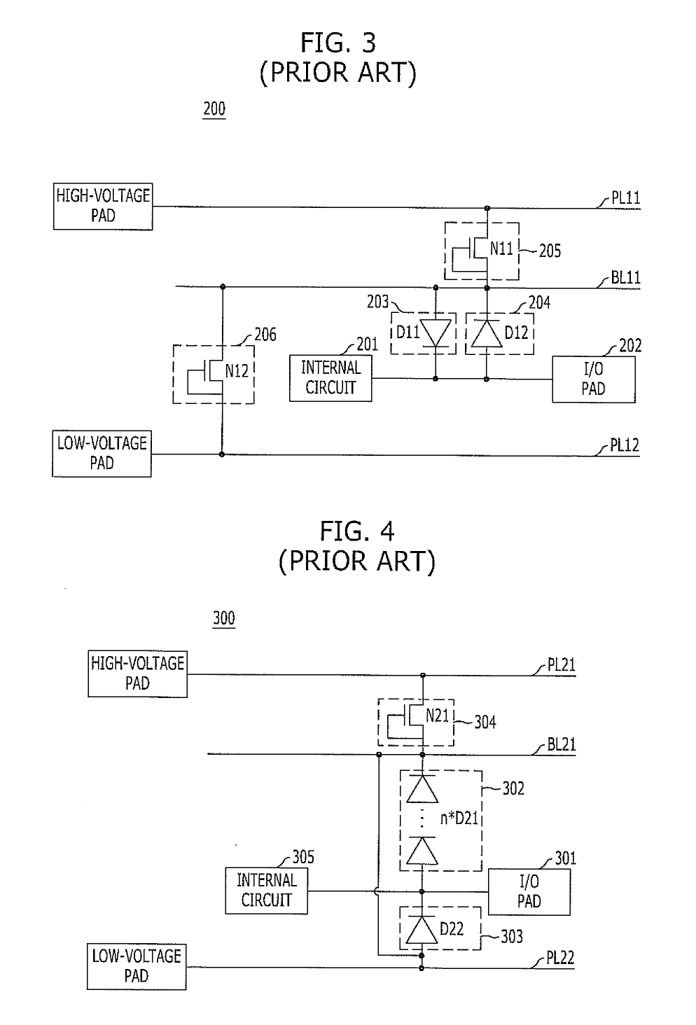

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

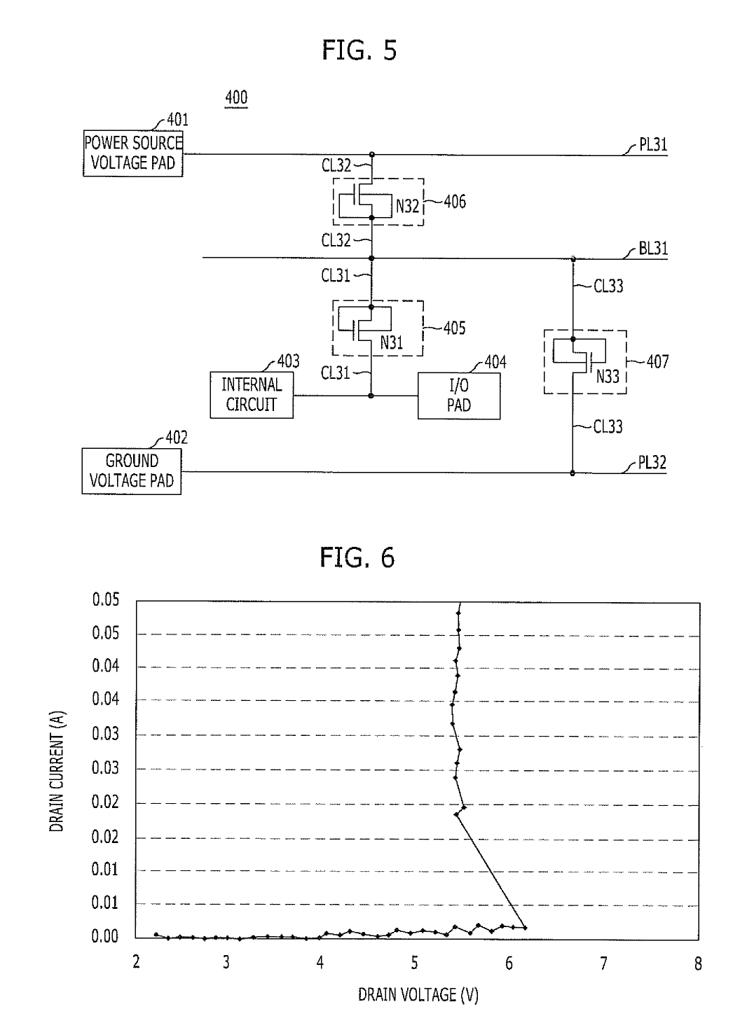

FIG. 5 is a block view of a semiconductor integrated circuit in accordance with a first embodiment of the present invention.

Referring to FIG. 5, the semiconductor integrated circuit 400 includes a power source voltage pad 401, a power source voltage line PL31, a ground voltage pad 402, a ground voltage line PL32, an electrostatic discharge bus line BL31, an input/output pad 404, a first electrostatic discharge unit 405, a second electrostatic discharge unit 406, a third electrostatic discharge unit 407, where the lines are conductive lines.

The power source voltage pad 401 receives a power source voltage VDD. The power source voltage line PL31 is coupled with the power source voltage pad 401. The ground voltage pad 402 receives a ground voltage VSS. The ground voltage line PL32 is coupled with the ground voltage pad 402. The electrostatic discharge bus line BL31 is in a floating state. The input/output pad 404 inputs/outputs a signal between an internal circuit 403 and an external circuit (not shown). The first electrostatic discharge unit 405 is coupled through a first common line CL31 between the input/output pad 404 and the electrostatic discharge bus line BL31 and provides a bi-directional electrostatic discharge path between the input/output pad 404 and the electrostatic discharge bus line BL31 according to an electrostatic discharge mode. The second electrostatic discharge unit 406 is coupled through a second common line CL32 between the power source voltage line PL31 and the electrostatic discharge bus line BL31 and provides a bi-directional electrostatic discharge path between the power source voltage line PL31 and the electrostatic discharge bus line BL31 according to an electrostatic discharge mode. The third electrostatic discharge unit 407 is coupled through a third common line CL33 between the electrostatic discharge bus line BL31 and the ground voltage line PL32 and provides a bi-directional electrostatic discharge path between the electrostatic discharge bus line BL31 and the ground voltage line PL32 according to an electrostatic discharge mode.

The first electrostatic discharge unit 405 includes a first NMOS transistor N31 that has a gate, a source and a substrate coupled with the electrostatic discharge bus line BL31 and a drain coupled with the input/output pad 404. The second electrostatic discharge unit 406 includes a second NMOS transistor N32 that has a gate, a source and a substrate coupled with the electrostatic discharge bus line BL31 and a drain coupled with the power source voltage line PL31. The third electrostatic discharge unit 407 includes a third NMOS transistor N33 that has a gate, a source and a substrate coupled with the electrostatic discharge bus line BL31 and a drain coupled with the ground voltage line PL32.

The first to third electrostatic discharge units 405, 406 and 407 that are formed to have the above-described structure are turned on as a bipolar junction transistor (BJT) or a diode according to an electrostatic discharge mode and provide an electrostatic discharge path according to the electrostatic discharge mode.

The electrostatic discharge mode includes a first electrostatic discharge mode for discharging static electricity introduced through the input/output pad 404 to the power source voltage pad 401, a second electrostatic discharge mode for discharging static electricity introduced through the power source voltage pad 401 to the input/output pad 404, a third electrostatic discharge mode for discharging static electricity introduced through the input/output pad 404 to the ground voltage pad 402, and a fourth electrostatic discharge mode for discharging static electricity introduced through the ground voltage pad 402 to the input/output pad 404.

Therefore, the first electrostatic discharge unit 405 is turned on as a bipolar junction transistor (BJT) and the second electrostatic discharge unit 406 is turned on as a diode in the first electrostatic discharge mode. The second electrostatic discharge unit 406 is turned on as a bipolar junction transistor (BJT) and the first electrostatic discharge unit 405 is turned on as a diode in the second electrostatic discharge mode. The first electrostatic discharge unit 405 is turned on as a bipolar junction transistor (BJT) and the third electrostatic discharge unit 407 is turned on as a diode in the third electrostatic discharge mode. The third electrostatic discharge unit 407 is turned on as a bipolar junction transistor (BJT) and the first electrostatic discharge unit 405 is turned on as a diode in the fourth electrostatic discharge mode.

Meanwhile, during a test mode, the electrostatic discharge mode includes a VDD positive mode, a VDD negative mode, a VSS positive mode, and a VSS negative mode. In the VDD positive mode, a positive (+) voltage is applied through the input/output pad 404 while the power source voltage pad 401 is coupled with a ground voltage VSS terminal. In the VDD negative mode, a negative (−) voltage is applied through the input/output pad 404 while the power source voltage pad 401 is coupled with the ground voltage VSS terminal. In the VSS positive mode, a positive (+) voltage is applied through the input/output pad 404 while the ground voltage pad 402 is coupled with the ground voltage VSS terminal. In the VSS negative mode, a negative (−) voltage is applied through the input/output pad 404 while the ground voltage pad 402 is coupled with the ground voltage VSS terminal. The electrostatic discharge path of the VDD positive mode is the same as the first electrostatic discharge mode, and the electrostatic discharge path of the VDD negative mode is the same as the second electrostatic discharge mode. The electrostatic discharge path of the VSS positive mode is the same as the third electrostatic discharge mode, and the electrostatic discharge path of the VSS negative mode is the same as the fourth electrostatic discharge mode.

As described above, in the semiconductor integrated circuit 400, two electrostatic discharge units (405 and 406 or 405 and 407) provide an electrostatic discharge path in the first to fourth electrostatic discharge modes. Therefore, the turn-on characteristics of a bipolar junction transistor and a diode are the same in all electrostatic discharge modes so that the operation voltage is the same in all electrostatic discharge modes. Therefore, it is easy to estimate electrostatic discharge characteristics. Also, since two parasitic capacitors are serially coupled in the electrostatic discharge path provided in all electrostatic discharge modes, the junction capacitance reflected into the input/output pad 404 is minimized/reduced.

Meanwhile, although the case where the first electrostatic discharge unit 405 includes one first NMOS transistor N31. is taken as an example and illustrated, the exemplary embodiment of the present invention is not limited to such disclosure so that, for example, the first electrostatic discharge unit 405 may include more than two first NMOS transistors N31 according to the voltage level in the high voltage environment. The turn-on voltage when the first NMOS transistor N31 performs a parasitic bipolar operation is approximately 6V as shown in FIG. 6, which illustrates turn-on characteristics during a parasitic bipolar operation of an NMOS transistor. Therefore, one first NMOS transistor N31 is provided in a high voltage environment having a voltage equal to or lower than approximately 6V, and two first NMOS transistors N31 are provided in a high voltage environment having a voltage equal to or lower than approximately 12V, and three first NMOS transistors N31 are provided in a high voltage environment having a voltage equal to or lower than approximately 182V. In this way, leakage current may be minimized/reduced.

The number of the first NMOS transistors N31 is increased in proportion to the voltage level of the high voltage environment, but the increase in the area of the semiconductor integrated device may still be reduced. When the turn-on voltage of a diode is approximately 1V, the turn-on voltage of approximately 6V may be obtained, for example, by serially connecting 6 diodes. Therefore, the number of diodes increases in proportion to an increase in a voltage level of the high voltage environment. Therefore, the technology of the present invention may minimize/reduce the area in a high voltage environment.

Hereafter, the operation of the semiconductor integrated circuit 400 in accordance with the first embodiment that has the above-described structure is described.

Since the first to fourth electrostatic discharge modes correspond to the VDD positive mode, the VDD negative mode, the VSS positive mode, and the VSS negative mode as described before, the VDD positive mode, the VDD negative mode, the VSS positive mode, and the VSS negative mode are described below.

In the VDD positive mode, a high voltage (e.g., approximately 2000V) corresponding to positive static electricity is applied through the input/output pad 404 while the power source voltage pad 401 is coupled with the ground voltage VSS terminal. Thus, the first electrostatic discharge unit 405 is turned on as a bipolar junction transistor (BJT), and the second electrostatic discharge unit 406 is turned on as a diode, discharging electrostatic current to the power source voltage pad 401.

In the VDD negative mode, a low voltage (e.g., approximately −2000V) corresponding to negative static electricity is applied through the input/output pad 404 while the power source voltage pad 401 is coupled with the ground voltage VSS terminal. Thus, the second electrostatic discharge unit 406 is turned on as a bipolar junction transistor (BJT), and the first electrostatic discharge unit 405 is turned on as a diode, discharging electrostatic current to the input/output pad 404.

In the VSS positive mode, a high voltage (e.g., approximately 2000V) corresponding to positive static electricity is applied through the input/output pad 404 while the ground voltage pad 402 is coupled with the ground voltage VSS terminal. Thus, the first electrostatic discharge unit 405 is turned on as a bipolar junction transistor (BJT), and the third electrostatic discharge unit 407 is turned on as a diode, discharging electrostatic current to the ground voltage pad 402.

In the VSS negative mode, a low voltage (e.g., approximately −2000V) corresponding to negative static electricity is applied through the input/output pad 404 while the ground voltage pad 402 is coupled with the ground voltage VSS terminal. Thus, the third electrostatic discharge unit 407 is turned on as a bipolar junction transistor (BJT), and the first electrostatic discharge unit 405 is turned on as a diode, discharging electrostatic current to the input/output pad 404.

According to the first embodiment of the present invention, since two electrostatic discharge units provide an electrostatic discharge path in all electrostatic discharge modes, the turn-on operations are the same (that is, threshold voltages to turn on a discharge path across two selected discharge units are the same regardless of which two pads that the discharge current flows across and regardless of the current flow direction) and thus the operation voltages are the same. Thus, an electrostatic discharge operations may be easily estimated to minimize the junction capacitance at the input/output pad. Also, the number of switching devices that are provided additionally according to the voltage level of the high voltage environment may be minimized/reduced by using an NMOS transistor as a switching device of an electrostatic discharge unit instead of a diode. Therefore, the increase in the area of the semiconductor integrated device may be minimized/reduced.

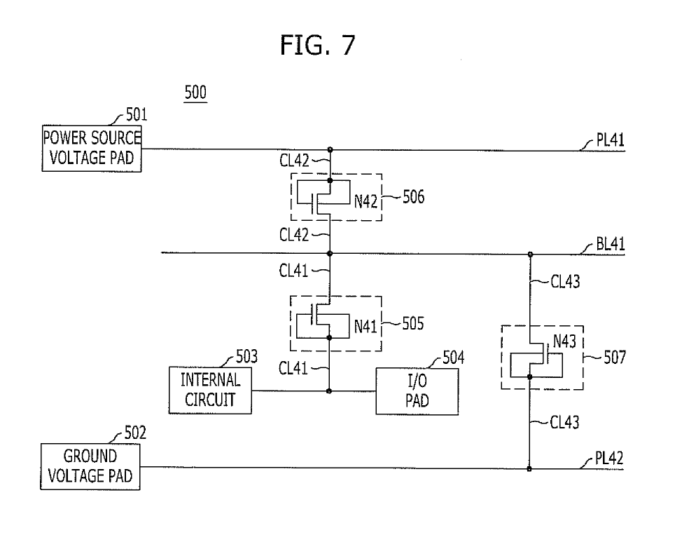

Meanwhile, the first embodiment of the present invention exemplarily illustrates a case where the electrostatic discharge unit in the front part of the respective discharge path operates as a bipolar junction transistor (BJT) and the electrostatic discharge unit in the rear part of the respective discharge path operates as a diode when two electrostatic discharge units provide an electrostatic discharge path according to the first to fourth electrostatic discharge modes. However, the exemplary embodiment of the present invention is not limited to such a disclosure, so that, for example, the electrostatic discharge unit in the front part may operate as a diode and the electrostatic discharge unit in the rear part may operate as a bipolar junction transistor (BJT). In other words, the same operation of the present invention described above may be performed although the source and drain of the NMOS transistor included in the first to third electrostatic discharge units are coupled in the opposite way. This is illustrated in FIG. 7.

FIG. 7 is a block view of a semiconductor integrated circuit 500 in accordance with a second embodiment of the present invention.

Referring to FIG. 7, the semiconductor integrated circuit 500 includes a power source voltage pad 501, a power source voltage line PL41, a ground voltage pad 502, a ground voltage line PL42, an electrostatic discharge bus line BL41, an input/output pad 504, a first NMOS transistor N41, a second NMOS transistor N42, and a third NMOS transistor N43.

The power source voltage pad 501 receives a power source voltage VDD. The power source voltage line PL41 is coupled with the power source voltage pad 501. The ground voltage pad 502 receives a ground voltage VSS. The second NMOS transistor N42 is coupled with the ground voltage pad 502. The electrostatic discharge bus line BL41 is in a floating state. The input/output pad 504 inputs/outputs a signal between an internal circuit 503 and an external circuit (not shown). The first NMOS transistor N41 includes a drain coupled with the electrostatic discharge bus line BL41 and a gate, a source and a substrate that are coupled with the input/output pad 504. The second NMOS transistor N42 includes a drain coupled with the electrostatic discharge bus line BL41 and a gate, a source and a substrate that are coupled with the power source voltage line PL41. The third NMOS transistor N43 includes a drain coupled with the electrostatic discharge bus line BL41 and a gate, a source and a substrate that are coupled with the ground voltage line PL42.

The overall operation and advantageous effects of the semiconductor integrated circuit 500 having the above structure are the same as those of the first embodiment of the present invention as described before, except that the sources and drains of the first to third NMOS transistors N41, N42 and N43 are coupled in the opposite way. For the purpose of avoiding redundancy, the operation and advantageous effects of the semiconductor integrated circuit 500 having the same structure in accordance with the second embodiment of the present invention are omitted herein.

According to an embodiment of the present invention, the number of switching devices that are additionally provided according to a high voltage environment may be minimized/reduced by using a

MOS transistor instead of a diode as a switching device of an electrostatic discharge unit. Therefore, as the voltage level of the high voltage environment increases, the area that is increased due to the presence of the electrostatic discharge unit may be minimized/reduced.

Also, as an electrostatic discharge protection circuit for protecting internal circuits from static electricity operates at the same turn-on points for all electrostatic discharge modes (that is, threshold voltages to turn on a discharge path across two selected discharge units are the same regardless of which two pads that the discharge current flows across and regardless of the current flow direction), the junction capacitance at an input/output pad may be minimized/reduced while electrostatic discharge estimation is performed easily.

While the present invention has been described with respect to the specific embodiments, it will be apparent to those skilled in the art that various changes and modifications may be made without departing from the spirit and scope of the invention as defined in the following claims.

What is claimed is:

1. A semiconductor integrated circuit, comprising:
a first conductive line coupled with a first pad for receiving a first voltage;
a second conductive line coupled with a second pad for receiving a second voltage;
a third conductive line arranged to be placed in a floating state;
a first electrostatic discharge unit coupled between a third pad for inputting/outputting a signal and the third conductive line through a first common conductive line, wherein the first electrostatic discharge unit is configured to provide a bi-directional electrostatic discharge path between the third pad and the third conductive line according to an electrostatic discharge mode;
a second electrostatic discharge unit coupled between the first conductive line and the third conductive line through a second common conductive line, wherein the second electrostatic discharge unit is configured to provide a bi-directional electrostatic discharge path between the first conductive line and the third conductive line according to the electrostatic discharge mode; and
a third electrostatic discharge unit coupled between the second conductive line and the third conductive line through a third common conductive line, wherein the third electrostatic discharge unit is configured to provide a bi-directional electrostatic discharge path between the second conductive line and the third conductive line according to the electrostatic discharge mode.

2. The semiconductor integrated circuit of claim 1, wherein two of the first to third electrostatic discharge units are configured to be randomly paired according to the electrostatic discharge mode to provide an electrostatic discharge path through the paired discharge units.

3. The semiconductor integrated circuit of claim 2, wherein the different pairs of the randomly paired electrostatic discharge units have the same trigger voltage across the unit pair regardless of which pair is selected according to the electrostatic discharge mode.

4. The semiconductor integrated circuit of claim 1, wherein the electrostatic discharge mode comprises:
a first electrostatic discharge mode for discharging static electricity introduced through the third pad to the first pad;
a second electrostatic discharge mode for discharging static electricity introduced through the first pad to the third pad;
a third electrostatic discharge mode for discharging static electricity introduced through the third pad to the second pad; and
a fourth electrostatic discharge mode for discharging static electricity introduced through the second pad to the third pad.

5. A semiconductor integrated circuit, comprising:
a first pad arranged to receive a first voltage;
a first conductive line coupled with the first pad;
a second pad arranged to receive a second voltage;
a second conductive line coupled with the second pad;
a third conductive line in a floating state;
a third pad arranged to input/output a signal between an internal circuit and an external circuit;
a first NMOS transistor including a gate, a source, and a substrate that are coupled with the third conductive line and including a drain coupled with the third pad;
a second NMOS transistor including a gate, a source, and a substrate that are coupled with the third conducive line and including a drain coupled with the first conductive line; and
a third electrostatic discharge unit including a gate, a source, and a substrate that are coupled with the third conductive line and including a drain coupled with the second conductive line.

6. The semiconductor integrated circuit of claim 5, wherein each of the first to third NMOS transistors is configured to be turned on as a bipolar junction transistor (BJT) or a diode according to an electrostatic discharge mode.

7. The semiconductor integrated circuit of claim 6, wherein a pair of the first to third NMOS transistors are configured to be selected to provide an electrostatic discharge path through the transistor pair according to the electrostatic discharge mode.

8. The semiconductor integrated circuit of claim 6, wherein the electrostatic discharge mode comprises:
a first electrostatic discharge mode for discharging static electricity introduced through the third pad to the first pad;
a second electrostatic discharge mode for discharging static electricity introduced through the first pad to the third pad;
a third electrostatic discharge mode for discharging static electricity introduced through the third pad to the second pad; and
a fourth electrostatic discharge mode for discharging static electricity introduced through the second pad to the third pad.

9. The semiconductor integrated circuit of claim 8, wherein the first NMOS transistor is configured to be turned on as the bipolar junction transistor (BJT) and the second NMOS transistor is configured to be turned on as the diode in the first electrostatic discharge mode.

10. The semiconductor integrated circuit of claim 8, wherein the second NMOS transistor is configured to be turned on as the bipolar junction transistor (BJT) and the first NMOS transistor is configured to be turned on as the diode in the second electrostatic discharge mode.

11. The semiconductor integrated circuit of claim 8, wherein the first NMOS transistor is configured to be turned on as the bipolar junction transistor (BJT) and the third NMOS transistor is configured to be turned on as the diode in the third electrostatic discharge mode.

12. The semiconductor integrated circuit of claim 8, wherein the third NMOS transistor is configured to be turned on as the bipolar junction transistor (BJT) and the first NMOS transistor is configured to be turned on as the diode in the fourth electrostatic discharge mode.

13. A semiconductor integrated circuit, comprising:
a first pad arranged to receive a first voltage;
a first conductive line coupled with the first pad;
a second pad arranged to receive a second voltage;
a second conductive line coupled with the second pad;
a third conductive line arranged to be placed in a floating state;
a third pad arranged to input/output a signal between an internal circuit and an external circuit;
a first NMOS transistor including a drain coupled with the third conductive line and including a gate, a source, and a substrate that are coupled with the third pad;
a second NMOS transistor including a drain coupled with the third conductive line and including a gate, a source, and a substrate that are coupled with the first conductive line; and
a third NMOS transistor including a drain coupled with the third conductive line and including a gate, a source, and a substrate that are coupled with the second conductive line.

14. The semiconductor integrated circuit of claim 13, wherein each of the first to third NMOS transistors is configured to be turned on as a bipolar junction transistor (BJT) or a diode according to an electrostatic discharge mode.

15. The semiconductor integrated circuit of claim 14, wherein a pair of the first to third NMOS transistors are selected to provide an electrostatic discharge path through the transistor pair according to the electrostatic discharge mode.

16. The semiconductor integrated circuit of claim 14, wherein the electrostatic discharge mode comprises:
a first electrostatic discharge mode for discharging static electricity introduced through the third pad to the first pad;
a second electrostatic discharge mode for discharging static electricity introduced through the first pad to the third pad;
a third electrostatic discharge mode for discharging static electricity introduced through the third pad to the second pad; and
a fourth electrostatic discharge mode for discharging static electricity introduced through the second pad to the third pad.

17. The semiconductor integrated circuit of claim 16, wherein the first NMOS transistor is configured to be turned on as the diode and the second NMOS transistor is configured to be turned on as the bipolar junction transistor (BJT) in the first electrostatic discharge mode.

18. The semiconductor integrated circuit of claim 16, wherein the second NMOS transistor is configured to be turned on as the diode and the first NMOS transistor is configured to be turned on as the bipolar junction transistor (BJT) in the second electrostatic discharge mode.

19. The semiconductor integrated circuit of claim 16, wherein the first NMOS transistor is configured to be turned on as the diode and the third NMOS transistor is configured to be turned on as the bipolar junction transistor (BJT) in the third electrostatic discharge mode.

20. The semiconductor integrated circuit of claim 16, wherein the third NMOS transistor is configured to be turned on as the diode and the first NMOS transistor is configured to be turned on as the bipolar junction transistor (BJT) in the fourth electrostatic discharge mode.

21. A semiconductor integrated circuit comprising:
first to third electrostatic discharge units that are each configured to be turned on as a diode or a transistor switch depending upon a polarity of voltage applied across the electrostatic discharge unit; and
first to third pads coupled to a common conductive line through the first to third electrostatic discharge units, respectively,
wherein in an electrostatic discharge path formed between a third pad and one of the first and second pads, a trigger voltage to turn on the electrostatic discharge path is the same regardless of whether the electrostatic discharge path is formed to flow current in one direction or in an opposite direction and the trigger voltage is the same regardless of whether the electrostatic discharge path formed between the third pad and the first pad or between the third pad and the second pad.

22. The semiconductor integrated circuit of claim 21, wherein the trigger voltage is the same as a trigger voltage to turn on an electrostatic discharge path formed between first and second pads.

23. The semiconductor integrated circuit of claim 21, wherein the electrostatic discharge path includes at least one turned on diode and at least one turned on transistor.

24. The semiconductor integrated circuit of claim 21, wherein the electrostatic discharge path is formed when voltages are applied across two pads.
